(19) United States
(12) Patent Application Publication
(10) Pub. No.: US 2015/0181684 A1
(43) Pub. Date: Jun. 25, 2015

(54) EXTREME EDGE AND SKEW CONTROL IN ICP PLASMA REACTOR

(71) Applicant: Applied Materials, Inc., Santa Clara, CA (US)

(72) Inventors: Samer BANNA, San Jose, CA (US); Vladimir KNYAZIK, Palo Alto, CA (US); Kyle TANTIWONG, Livermore, CA (US)

(21) Appl. No.: 14/543,316

(22) Filed: Nov. 17, 2014

Related U.S. Application Data
(60) Provisional application No. 61/920,226, filed on Dec. 23, 2013.

(51) Int. Cl. H05H 1/24; H01L 21/67; H01L 21/3065

(52) U.S. Cl. CPC H05H 1/24; H01L 21/3065; H01L 21/67069

(57) ABSTRACT

Embodiments of the present disclosure provide apparatus and methods for improving plasma uniformity around edge regions and/or reducing non-symmetry in a plasma processing chamber. One embodiment of the present disclosure provides a plasma tuning assembly having one or more conductive bodies disposed around an edge region of a substrate support in a plasma processing chamber. The one or more conductive bodies are isolated from other chamber components and electrically floating in the processing chamber near the edge region without connecting to active electrical potentials. During operation, when a plasma is maintained in the plasma processing chamber, the presence of the one or more conductive bodies affects the plasma distribution near the one or more conductive bodies.

### CROSS-REFERENCE TO RELATED APPLICATIONS

This application claims benefit of U.S. Provisional Patent Application Ser. No. 61/920,226 filed Dec. 23, 2013, which is herein incorporated by reference.

### BACKGROUND

1. Field

Embodiments of the present disclosure relate to apparatus and methods for processing semiconductor substrates. More particularly, embodiments of the present disclosure relate to apparatus and methods for improving across wafer process uniformity around edge region of the wafer and/or reducing/controlling overall process skew in a plasma reactor mainly induced at wafer edge region.

2. Description of the Related Art

Plasma processing reactors are commonly used in semiconductor processing. In semiconductor processing, edge regions of a substrate being processed are usually excluded from device formation, commonly known as edge exclusion, because processing environment around the edge region is not consistent with the processing environment near the center region of the substrate due to material and geometry discontinuities near the edge region. However, there is a constant demand to reduce edge exclusion and improve overall wafer yield by extending the devices to the extreme edge of the wafer. Additionally, asymmetries in a processing chamber, such as the presence of slit valve door, off-set pumping path, or incoming wafer non-uniformities may cause non-symmetry in the processing environment resulting in process skew across the substrate.

Therefore, there is a need for a plasma processing chamber with improved edge uniformity and reduced process skew.

### SUMMARY

The present disclosure generally provides apparatus and method for improving process uniformity around wafer edge region and/or reducing/controlling processing skew in a plasma reactor.

One embodiment of the present disclosure provides a plasma tuning assembly. The plasma tuning assembly includes one or more conductive bodies configured to be disposed around a substrate supporting surface of a substrate support assembly in a plasma processing chamber. The one or more conductive bodies electrically float in the plasma processing chamber without in electrical contact with a chamber body and the substrate support assembly. The plasma tuning assembly further includes a support assembly for supporting the one or more conductive bodies in the plasma processing chamber.

Another embodiment of the present disclosure provides an apparatus for processing a substrate. The apparatus includes a chamber body defining a processing volume, a substrate support disposed in the processing volume, a plasma source for generating a plasma in the processing volume, and a plasma tuning assembly. The plasma tuning assembly includes one or more conductive bodies disposed around a substrate supporting surface of the substrate support assembly. The one or more conductive bodies electrically float in the processing volume without in electrical contact with the chamber body and the substrate support assembly. The plasma tuning assembly further includes a support assembly supporting the one or more conductive bodies in the plasma processing chamber.

Yet another embodiment of the present disclosure provides a method for processing a substrate. The method includes positioning a substrate on a substrate supporting surface of a substrate support assembly disposed in a processing volume of a plasma processing chamber, generating a plasma in the processing volume above the substrate, and tuning the plasma by positioning one or more conductive bodies around an edge region of the substrate. The one or more conductive bodies are electrically isolated from other chamber components.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A is a schematic top view of a plasma processing chamber according to one embodiment of the present disclosure.

FIG. 1B is a schematic sectional side view of the plasma processing chamber of FIG. 1A.

FIG. 1C is a schematic perspective view of the plasma processing chamber of FIG. 1A.

FIG. 2 is a schematic sectional side view of a plasma processing chamber according to another embodiment of the present disclosure.

FIG. 3A is a schematic top view of a plasma processing chamber according to one embodiment of the present disclosure.

FIG. 3B is a schematic perspective view of a plasma tuning assembly of the plasma processing chamber of FIG. 3A.

FIG. 4 is a schematic top view of a plasma tuning assembly according to another embodiment of the present disclosure.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the present disclosure provide apparatus and methods for improving plasma uniformity around edge regions and/or reducing non-symmetry in a plasma processing chamber. One embodiment of the present disclosure provides a plasma tuning assembly having one or more conductive bodies disposed around an edge region of a substrate support in a plasma processing chamber. In one embodiment, the one or more conductive bodies are isolated from other chamber components and electrically floating in the processing chamber near the edge region without connecting to active electrical potentials. During operation, when a plasma is maintained in the plasma processing chamber, the presence of the one or more conductive bodies affects the plasma distribution near the one or more conductive bodies. The plasma may be tuned by positioning the one or more conductive bodies at various locations in the plasma processing chamber.

In another embodiment, each of the one or more conductive bodies may be grounded, for example, connected to a grounded chamber body, through a variable capacitor. By varying the value of the variable capacitor, the corresponding conductive body may provide varied effects to the plasma. The value of the variable capacitor and/or locations of the one or more conductive bodies may be adjusted to achieve a target tuning effect of the plasma.

In one embodiment, the one or more conductive bodies include a continuous conductive ring. The continuous conductive ring may be movably positioned in the processing chamber so that the continuous conductive ring may be moved relative to the substrate support to tune the plasma distribution around the edge region of the substrate support.

In another embodiment, the one or more conductive bodies include a plurality of ring segments that are electrically isolated from one another. Each of the plurality of ring segments may be controlled individually for correcting any non-symmetry in the plasma. The height, radial position, or value of a corresponding variable capacitor may be adjusted alone or in combination for each ring segment. The configuration of ring segments allows asymmetrical input to the plasma thus providing possible corrections to asymmetrical plasma distribution and reducing processing skew.

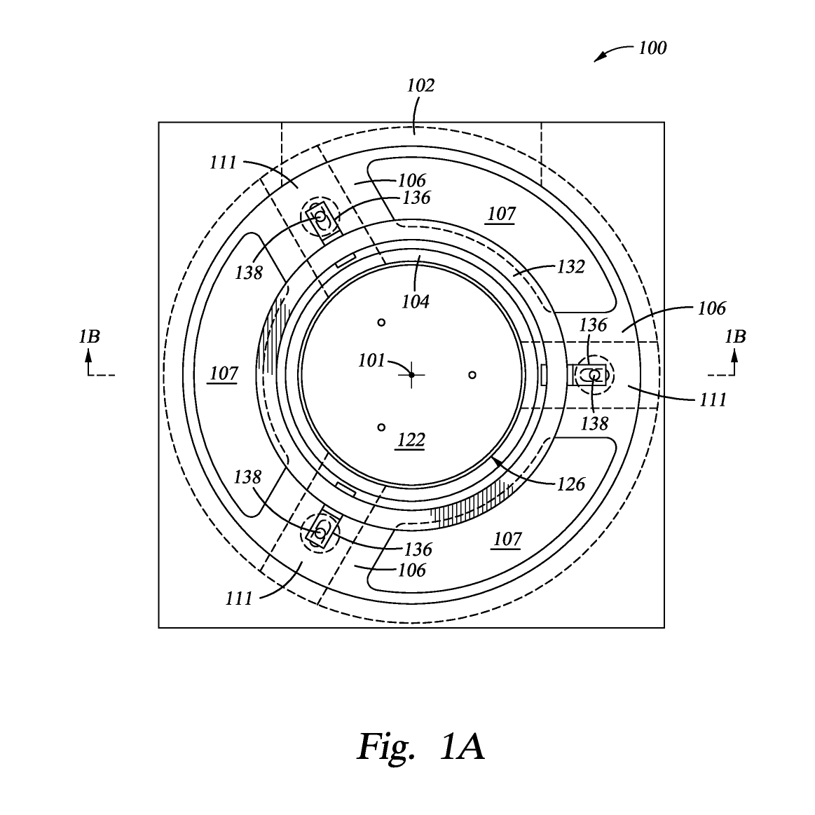

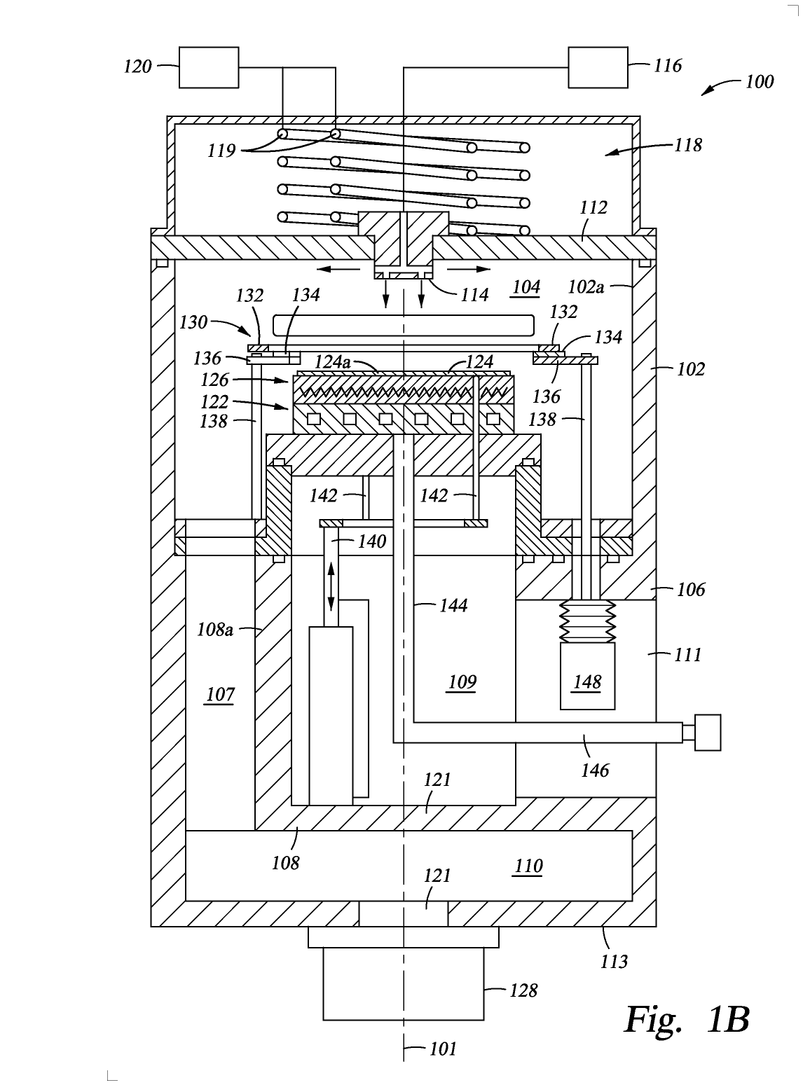

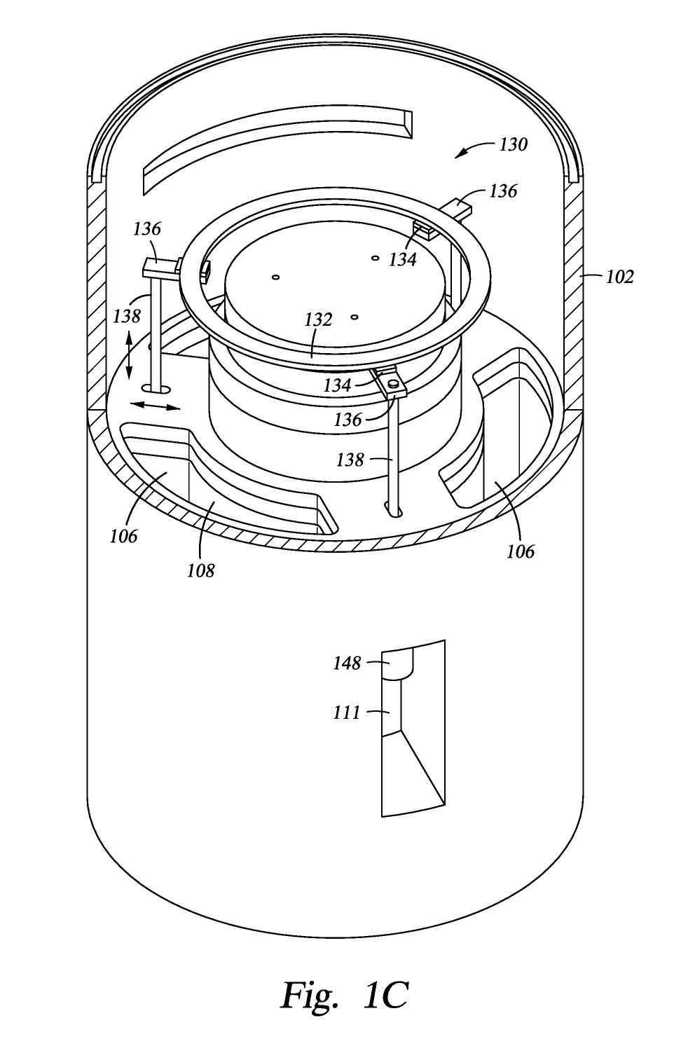

FIG. 1A is a schematic top view of a plasma processing chamber 100 with a lid and a plasma source removed. FIG. 1B is a schematic sectional side view of the plasma processing chamber 100. FIG. 1C is a schematic perspective view of the plasma processing chamber 100. The plasma processing chamber 100 includes a chamber body 102. A basin 108 is disposed within the chamber body 102 and connected to the chamber body through a plurality of spokes 106. The basin 108 and the plurality of spokes 106 are symmetrically positioned about a central axis 101 of the chamber body 102. Each spoke 106 may be hollow with an inner passage 111. The plurality of spokes 106 may be evenly distributed along sidewalls 108a of the basin 108. The basin 108 and the plurality of spokes 106 divide the interior of the chamber body 102 to a processing volume 104 in the upper portion and an evacuation volume 110 in the lower portion. The processing volume 104 and the evacuation volume 110 are connected by a plurality of vertical volumes 107 between the plurality of spokes 106.

A substrate support assembly 122 is disposed in the chamber body 102 over the basin 108. The substrate support assembly 122 is configured to support a substrate 124 while the substrate 124 is being processed in the processing volume 104. The substrate support assembly 122 may have a substrate supporting plane 124a positioned to be symmetric about the central axis 101.

The substrate support assembly 122 isolates a basin volume 109 from processing volume 104 and the evacuation volume 110. The basin volume 109 may be connected to the exterior of the chamber body 102 through the inner passages 111 of the plurality of spokes 106. A lift pin assembly 140 may be disposed in the basin volume 109 for moving lift pins 142 to raise or lower the substrate 124. A shaft 144 in the basin volume 109 and a duct 146 connected to the shaft 144 through the inner passage 111 of the poke 106 may be used to house connections to the substrate support assembly 122, such as leads to embedded heater, leads to an electrode, conduits for circulating cooling fluid, and the like.

A plasma generator 118 may be disposed over a lid 112 of the chamber body 102. A gas distribution nozzle 114 may be positioned through the lid 112 to deliver one or more processing gas to the processing volume 104. The gas distribution nozzle 114 may be connected to a gas panel 116. The plasma generator 118 is positioned to ignite and maintain a plasma within the processing volume 104. As shown in FIG. 1B, the plasma generator 118 may be an inductive coupled plasma source having one or more coils 119 connected to a radio frequency (RF) power source. In one embodiment, the plasma generator 118 and the gas distribution nozzle 114 may be symmetrically positioned about the central axis 101.

A vacuum port 121 may be formed through a bottom 113 of the chamber body 102. The vacuum port 121 may be symmetric about the central axis 101. A pumping system 128 may be coupled to the vacuum port 121 to maintain a low pressure environment in the plasma processing chamber 100. The symmetrically arranged gas distribution nozzle 114, substrate support assembly 122, basin 108, spokes 106 and vacuum port 121 facilitates a substantially symmetrical flow paths within the plasma processing chamber 100.

The plasma processing chamber 100 further includes a plasma tuning assembly 130 configured to adjusting plasma distribution within the processing volume 104. In FIGS. 1A and 1B, the plasma tuning assembly 130 includes a conductive ring 132 disposed about an edge region 126 of the substrate support assembly 122. In one embodiment, the conductive ring 132 may be positioned between an inner wall 102a of the chamber body 102 and the edge region 126 of the substrate support assembly 122 and horizontally above the substrate 124 supported by the substrate support assembly 122. The conductive ring 132 forms one continuous conductive body. The conductive ring 132 may be a unitary ring or multiple ring sections electrically connected to one another.

The plasma tuning assembly 130 further includes a support assembly for positioning the conductive ring 132 in the plasma processing chamber 100. In one embodiment, the support assembly may include a plurality of supporting fingers 136 extending from a plurality of supporting posts 138. The conductive ring 132 is supported by the plurality of supporting fingers 136. An electrical insulator 134 may be disposed between the conductive ring 132 and each of the supporting fingers 136 so that the conductive ring 132 electrically floats in the processing volume 104 without electrical contact with any elements in the plasma processing chamber 100. During plasma processing, the RF field propagated from the plasma generator 118 may generate an electrical current within the closed loop of the conductive ring 132, resulting an electric potential in the conductive ring 132. The electrical potential in the conductive ring 132 alters the plasma cloud in the processing volume 104 and tunes the plasma. The continuous conductive ring 132 may shift the plasma cloud equally at edge region 126.

The conductive ring 132 may move relative to the substrate support assembly 122 shifting the plasma cloud to a target direction. As shown in FIG. 1B, each of the supporting posts 138 may be connected to an actuator 148. The actuator 148 may move the supporting post 138 vertically (parallel with the central axis 101) and/or horizontally (perpendicular to the central axis 101).

The plurality of supporting posts 138 may be moved in unison vertically and/or horizontally. The conductive ring 132 may be supported in a plane substantially parallel to the substrate supporting plane 124a. The vertical movement of the conductive ring 132 may be used to adjust degree of influence of the conductive ring 132 to the plasma around the edge region 126. The horizontal movement of the conductive ring 132 may be used to adjust the symmetry of the plasma cloud.

Alternatively, each of the supporting posts 138 may be independently. For example, each of the supporting posts 138 may be moved independently along the vertical direction so that the conductive ring 132 may be tilted relative to a substrate supporting plane 124a resulting in a variable adjustment along the periphery of the substrate support assembly 122 that can be used to compensate non-symmetry in the plasma and reduce processing skew.

The conductive ring 132 is formed from an electrically conductive material, such as metal. For example, the conductive ring 132 may be formed from aluminum, copper, stainless steel. In one embodiment, the conductive ring 132 may have a protective coating to prevent any attack from processing plasma. The protective coating may be a ceramic coating. In one embodiment, the protective coating may be an yttria coating.

The supporting posts 138 and the supporting fingers 136 may be formed from anodized aluminum. The insulator 134 may be formed from a polymer, such as TORLON®, a ceramic or anodized aluminum.

The plasma tuning assembly 130 may include components positioned substantially symmetrical about the central axis 101 to further improve chamber symmetry. As shown in FIG. 1B, each of the plurality of supporting posts 138 may extend through the plurality of spokes 106. The actuators 148 may be disposed in the inner passages 111 of the spokes 106.

The plasmas tuning assembly 130 of the plasma processing chamber 100 passively generates an electrical potential for plasma tuning. Alternative, the electrical potential of a plasma assembly may be actively controlled by connecting a conductive body inside a plasma processing chamber with control circuits. For example, a control circuit including a variable capacitance may be used to actively adjust the electrical potential of the conductive body inside the plasma chamber.

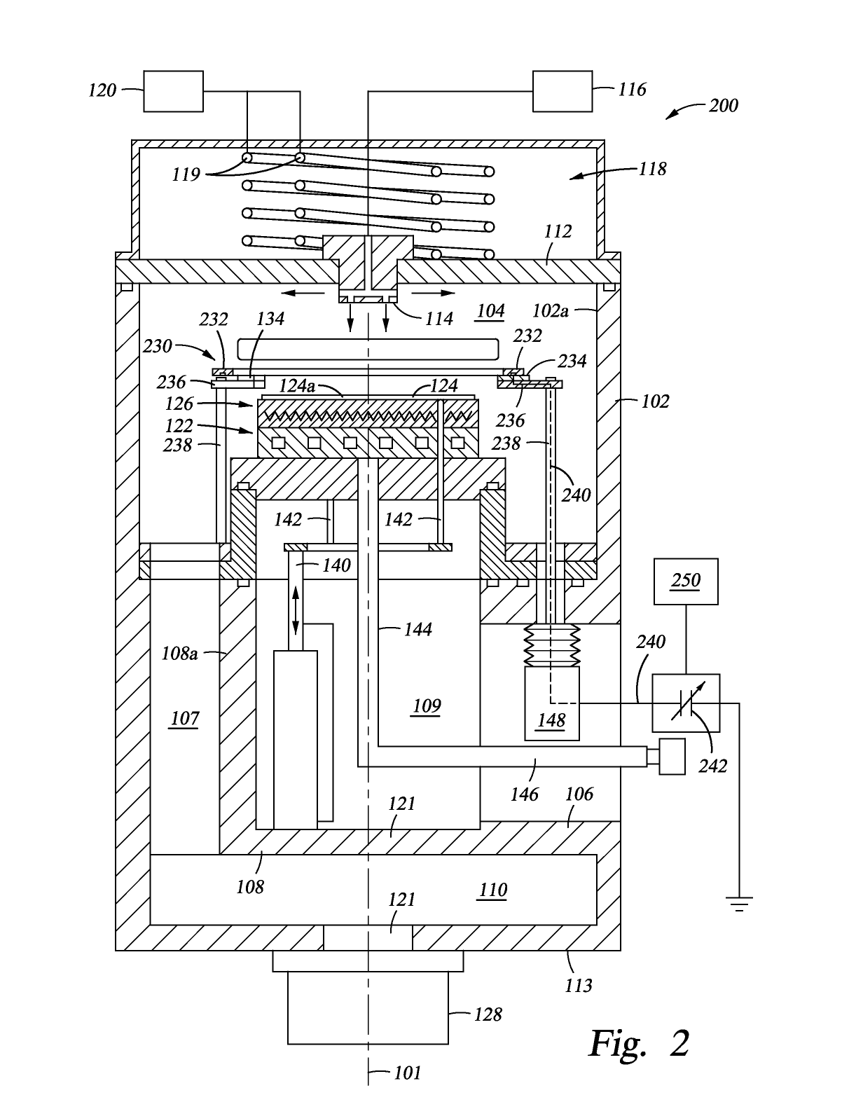

FIG. 2 is a schematic sectional side view of a plasma processing chamber 200 according to another embodiment of the present disclosure. The plasma processing chamber 200 is similar to the plasma processing chamber 100 except that the plasma processing chamber 200 includes a plasma tuning assembly 230 having a variable capacitor 242.

The plasma turning assembly 230 includes a conductive ring 232 positioned between an inner wall 102a of the chamber body 102 and the edge region 126 of the substrate support assembly 122. The conductive ring 232 is supported by a plurality of supporting fingers 236 extending from a plurality of supporting posts 238. An electrical insulator 234 may be disposed between the conductive ring 232 and each of the supporting fingers 236.

The conductive ring 232 is coupled to a variable capacitor 242 through a lead 240. The variable capacitor 242 may be disposed in an exterior of the chamber body 102. The lead 240 may be a conductive wire having an insulating layer so that the conductive wire and the conductive ring 232 remain electrically insulated from other components of the plasma processing chamber 200. The variable capacitor 242 has one electrode in electrical connection with the conductive ring 232 and an opposite electrode connected to the ground.

The presence of the variable capacitor 242 between the conductive ring 232 and the ground affects the electrical potential of the conductive ring 232 thus altering the tuning result of the conductive ring 232. The plasma near the edge region 126 of the substrate support assembly 122 may be tuned or adjusted by the electrical potential of the conductive ring 232, which may be adjusted by adjusting the capacitance of the variable capacitor 242. The variable capacitor 242 may be controlled by a system controller 250 to achieve target results.

Changing the capacitance of the variable capacitor 242 allows the plasma tuning assembly 230 to control the plasma potential close to the substrate edge near the edge region 126 of the substrate support assembly 122, thus, controlling the edge roll up/off.

In one embodiment, using the variable capacitor 242, the plasma tuning assembly 230 may achieve different tuning results without physically moving the conductive ring 232 relative to the substrate support assembly 122, thus reducing system complicity. Alternatively, the variable capacitor 242 may be used in combination with physical movement of the conductive ring 232 to increase the range of adjustment using variable capacitor alone or using physical movement alone.

According to embodiments of the present disclosure, multiple conductive bodies may be used in combination to tune the plasma in a plasma processing. In one embodiment, the multiple conductive bodies may be multiple arc segments forming a ring. Other arrangements, such as two or more rings of different diameters and/or at different height or elevation, may also be used.

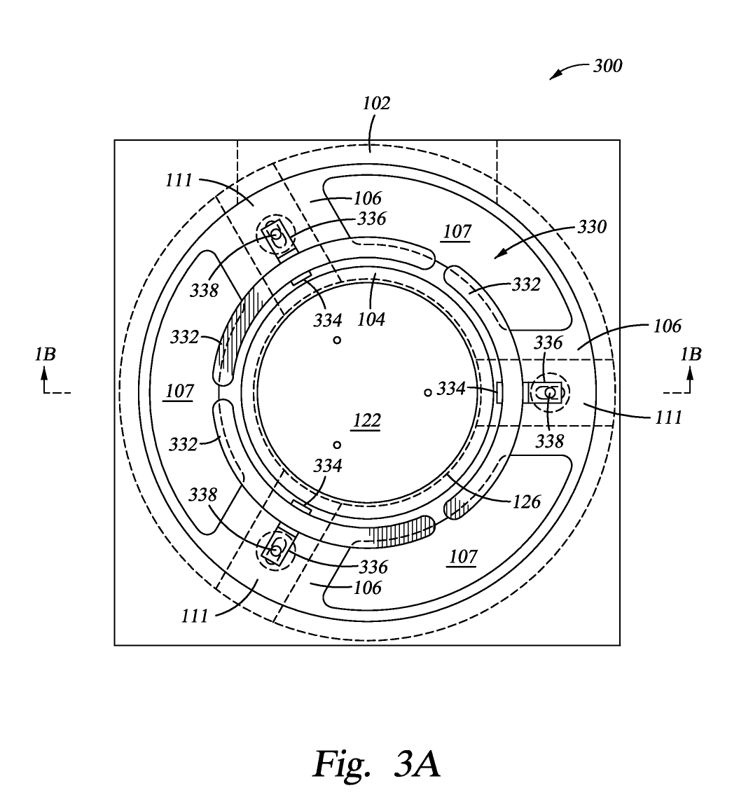

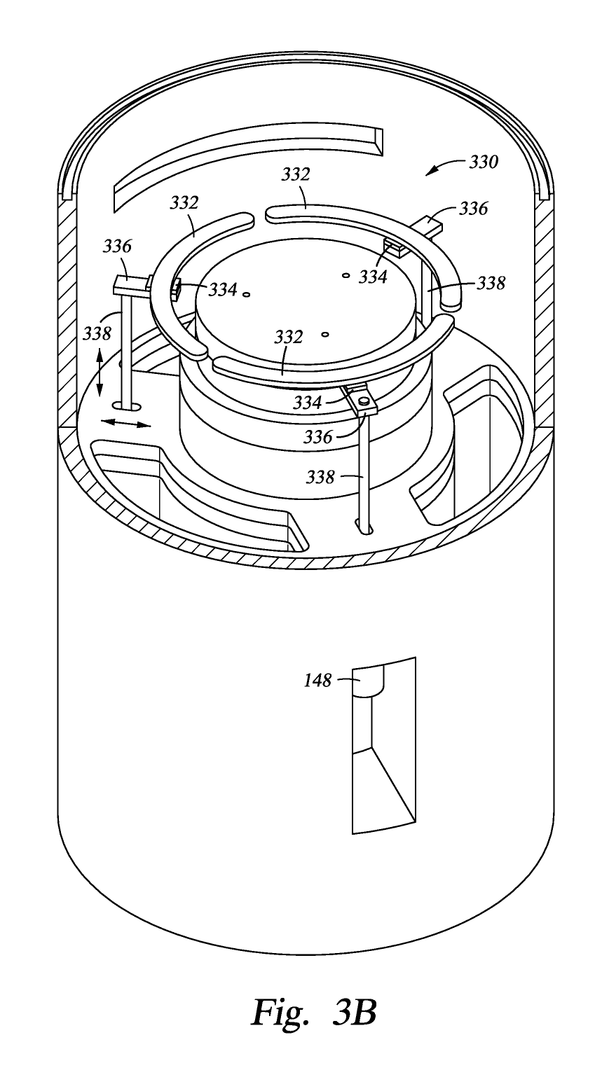

FIG. 3A is a schematic top view of a plasma processing chamber 300 according to one embodiment of the present disclosure. The plasma processing chamber 300 is similar to the plasma processing chamber 100 except that the plasma processing chamber 200 includes a plasma tuning assembly 330 having segmented conductive bodies. The plasma tuning assembly 330 includes a plurality of conductive segments 332 disposed radially outwards of the substrate support assembly 122. The plurality of conductive segments 332 may be ring segments that substantially form a ring. In one embodiment, the conductive segments 332 may be identical in shape, having the same arc length and the same diameter, and evenly distributed along a periphery of the substrate support assembly 122. As shown in FIG. 3A, the plasma tuning assembly 330 may include three identical conductive segments 332 distributed about 120 degrees apart from one another.

FIG. 3B is a schematic perspective view of the plasma tuning assembly 330 of the plasma processing chamber 300. As shown in FIG. 3B, each conductive segment 332 may be supported by a supporting finger 336, but not in electrical contact with the supporting finger 336. An insulator 334 may be disposed between the supporting finger 336 and the conductive segment 332 to provide electrical insulation. Each supporting finger 336 may extend from a supporting post 338. The supporting post 338 may be coupled to an actuator 340. The actuator 340 may move the supporting post 338, the supporting finger 336 and the conductive segment 332. In one embodiment, the conductive segments 332 may be moved vertically, parallel to the central axis 101, and horizontally along a radially direction. Each conductive segment 332 may be moved independently so that the conductive segments 332 may be positioned at different vertically levels and different radial locations. As s result, combinations of different locations of the plurality of conductive segments 332 allow a great flexible adjustment to the plasma. The plasma adjustment provided by the plurality of conductive segments 332 may be both symmetrical to the central axis 101 and non-symmetrical to the central axis 101, therefore, can be used to reduce processing skew.

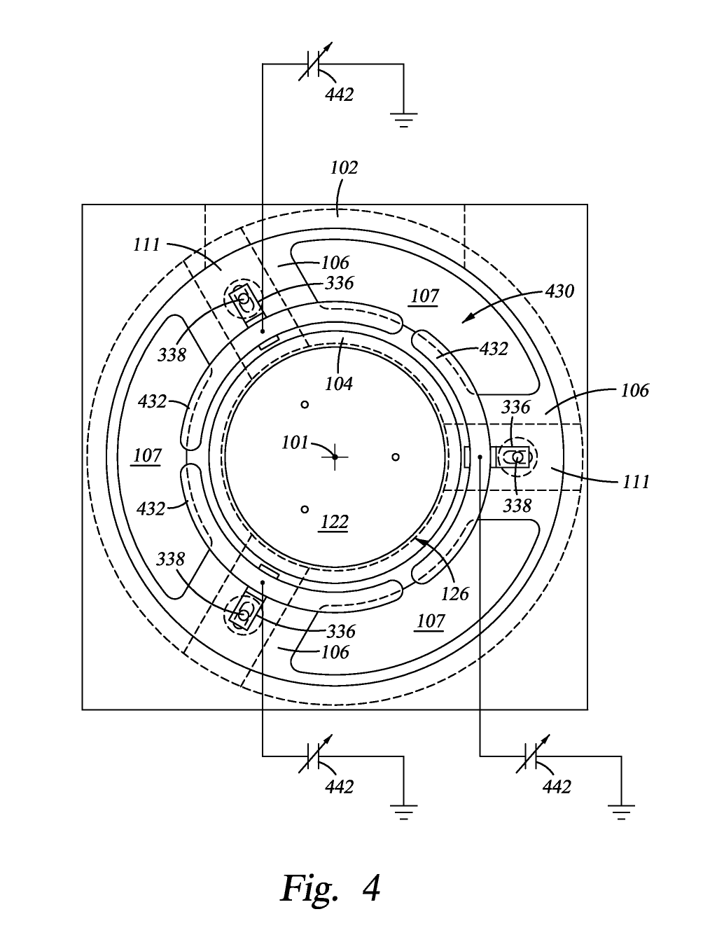

FIG. 4 is a schematic top view of a plasma tuning assembly 430 according to another embodiment of the present disclosure. The plasma tubing assembly 430 is similar to the plasma tuning assembly 330 except that the plasma tuning assembly 430 includes variable capacitors 442. The plasma tuning assembly 430 includes a plurality of conductive segments 432. Each conductive segment 432 is grounded through a variable capacitor 442. Each variable capacitor 442 may be adjusted independently. The variable capacitors 442 may be adjusted alone or in combination with physical movement of the conductive segments 432 to provide a target plasma tuning.

Even though the plasma tuning assemblies are described in association with a plasma processing chamber having substantially symmetrical pumping paths, the plasma tuning assemblies of the present disclosure may be used in plasma processing chambers having other geometry arrangements, for example a plasma processing chamber having non-concentric substrate support assembly and pumping port.

The plasma tuning assemblies according to the present disclosure provide plasma tuning to compensate various non-uniformity, non-symmetricity, and skews in a plasma processing chamber. For example, the non-uniformity, non-symmetricity, and skews caused by a gas delivery and pumping, RF delivery, chamber geometry, substrate temperature control system, or ambient magnetic field, can be compensated using the plasma tuning assembly of the present disclosure resulting in reduced process skew.

Even though applications with inductive coupled plasma are described above, embodiments of the present disclosure may be used with adjusting plasma generated by any plasma sources, such as capacitive coupled plasma, reactive ion etching reactor, electron cyclotron resonance, ion beam, remote plasma source, microwave plasma source, and combinations of plasma sources. While the foregoing is directed to embodiments of the present disclosure, other and further embodiments of the disclosure may be devised without departing from the basic scope thereof, and the scope thereof is determined by the claims that follow.

1. A plasma tuning assembly, comprising:
one or more conductive bodies configured to be disposed around a substrate supporting surface of a substrate support assembly in a plasma processing chamber, wherein the one or more conductive bodies electrically float in the plasma processing chamber without in electrical contact with a chamber body and the substrate support assembly; and
a support assembly for supporting the one or more conductive bodies in the plasma processing chamber.

2. The plasma tuning assembly of claim 1, wherein the one or more conductive bodies comprises a conductive ring disposed around the substrate supporting surface.

3. The plasma tuning assembly of claim 2, further comprising a variable capacitor having a first electrode electrically connected to the conductive ring and a second electrode grounded.

4. The plasma tuning assembly of claim 1, wherein the one or more conductive bodies comprises:
a plurality of conductive segments electrically isolated from one another.

5. The plasma tuning assembly of claim 4, wherein the plurality of conductive segments are arc segments of a ring, and the plurality of conductive segments substantially form a ring.

6. The plasma tuning assembly of claim 4, further comprising a plurality of variable capacitors, wherein each of the plurality of variable capacitors comprises a first electrode electrically connected to a corresponding one of conductive segment, and a second electrode connected to electrical ground.

7. The plasma tuning assembly of claim 1, wherein the support assembly comprises one or more actuators for moving the one or more conductive bodies in the plasma processing chamber.

8. The plasma tuning assembly of claim 7, wherein the support assembly further comprises:
a plurality of supporting fingers disposed within the plasma processing chamber for supporting the one or more conductive bodies; and
a plurality of supporting posts attached to the supporting fingers, wherein the one or more actuators are coupled to the plurality of supporting posts for moving the plurality of supporting posts, the plurality of supporting fingers and the one or more conductive bodies.

9. The plasma tuning assembly of claim 8, further comprising:
a plurality of electrical insulators disposed between the plurality of supporting fingers and the one or more conductive bodies.

10. The plasma tuning assembly of claim 1, wherein each of the one or more conductive bodies comprises a conductive core and a protective coating.

11. An apparatus for processing a substrate, comprising:
a chamber body defining a processing volume;
a substrate support disposed in the processing volume;
a plasma source for generating a plasma in the processing volume; and
a plasma tuning assembly, wherein the plasma tuning assembly comprises:
one or more conductive bodies disposed around a substrate supporting surface of the substrate support assembly, wherein the one or more conductive bodies electrically float in the processing volume without in electrical contact with the chamber body and the substrate support assembly; and
a support assembly supporting the one or more conductive bodies in the plasma processing chamber.

12. The apparatus of claim 11, wherein the one or more conductive bodies comprises a conductive ring disposed around the substrate supporting surface.

13. The apparatus of claim 12, wherein the conductive ring is positioned above the substrate supporting surface.

14. The apparatus of claim 12, further comprising a variable capacitor having a first electrode electrically connected to the conductive ring and a second electrode grounded.

15. The apparatus of claim 11, wherein the one or more conductive bodies comprises:
a plurality of conductive segments electrically isolated from one another.

16. The apparatus of claim 15, further comprising a plurality of variable capacitors, wherein each of the plurality of variable capacitors comprises a first electrode electrically connected to a corresponding one of conductive segment, and a second electrode connected to electrical ground.

17. The apparatus of claim 15, wherein the support assembly further comprises:
disposed within the plasma processing chamber for supporting the one or more conductive bodies; and
a plurality of supporting posts extending from the chamber body;
a plurality of supporting fingers attached to the plurality of supporting posts, and the one or more conductive bodies are supported by the plurality of fingers; and
one or more actuators are coupled to the plurality of supporting posts for moving the plurality of supporting posts, the plurality of supporting fingers and the one or more conductive bodies within the processing volume.

18. A method for processing a substrate, comprising:
positioning a substrate on a substrate supporting surface of a substrate support assembly disposed in a processing volume of a plasma processing chamber;
generating a plasma in the processing volume above the substrate; and
tuning the plasma by positioning one or more conductive bodies around an edge region of the substrate, wherein the one or more conductive bodies are electrically isolated from other chamber components.

19. The method of claim 18, wherein tuning the plasma comprising moving the one or more conductive bodies relative to the substrate.

20. The method of claim 18, wherein tuning the plasma comprising:
grounding the one or more conductive body through a variable capacitor; and
changing the capacitance of the variable capacitor.
